(19) United States
(12) Patent Application Publication
(10) Pub. No.: US 2021/0281276 A1
(43) Pub. Date: Sep. 9, 2021

(54) ENCODED BLOCK FORMAT

(71) Applicant: ANACODE LABS, INC., Watsonville, CA (US)

(72) Inventor: ALBERT W WEGENER, APTOS HILLS, CA (US)

(73) Assignee: ANACODE LABS, INC., Watsonville, CA (US)

(21) Appl. No.: 16/611,428

(22) PCT Filed: May 4, 2018
(86) PCT No.: PCT/US18/31061

§ 371 Date: Nov. 6, 2019

Related U.S. Application Data
(60) Provisional application No. 62/502,507, filed on May 5, 2017.

(51) Int. Cl. H03M 7/30; H03M 7/48; H04L 29/06

(52) U.S. Cl. CPC H03M 7/3088; H04L 69/04; H03M 7/48

(57) ABSTRACT

Encoded (compressed) data in an encoded block format output by a data encoder, having an input including digital input elements from an input stream or file that are divided into blocks that contain Nb individual data elements per block. The encoded block format can include an index that, during decoding, supports random access. A decoder can losslessly decode the encoded block format. Each encoded block contains a header and a payload. The header specifies the unique characteristics of elements used by the payload to describe single-Byte or multi-Byte events that occurred in the input block. The encoded block format is generated by one or more block-oriented encoders (compressors). Blocks having the encoded block format may be consumed by one or more decoders (decompressors) that regenerate Nb elements from each decoded (uncompressed) block.

### CROSS-REFERENCE TO OTHER APPLICATIONS

This application claims priority to U.S. Provisional Application No. 62/502,507 filed on 5 May 2017 (05.05.2017) (Any. Docket No.: ANAC 1001-1). The above application is incorporated by reference herein in its entirety.

### BACKGROUND OF THE INVENTION

Information processing and storage systems are being deluged by digital data. Especially since the advent of Cloud computing in the mid-2000s, information technology (IT) systems are processing, transferring and storing such digital data in large facilities called data centers. As data centers struggle with the digital data deluge, compression techniques that reduce the volume of bits to be processed, transmitted, and stored deliver practical and economic value.

### SUMMARY OF THE DISCLOSURE

The disclosed technology represents encoded (compressed) data in an encoded block format that can significantly reduce the number of bits required to perfectly represent the digital bits from original data blocks. Unlike prior art lossless encoders, the disclosed technology's encoded block format can be generated using a number of concurrent, independent encoders, in software or hardware, that simultaneously encode blocks of original digital input data into the encoded block format of the disclosed technology. Similarly, unlike prior art lossless decoders, the disclosed technology's encoded block format can regenerate (decode) the original digital data by using a number of concurrent, independent decoders, in software or hardware, that simultaneously decode blocks that were encoded in the disclosed technology's encoded block format.

The disclosed technology represents encoded (compressed) data in an encoded block format that is the output of a data encoder. The encoder's input includes digital input elements from an input stream or file that are divided into blocks that contain Nb individual data elements per block, where Nb is an integer. Typically, each input data element contains 8 bits (1 Byte). Typically, Nb may optionally be restricted to a predetermined range of [min, max] block sizes, such as [512 B, 16 MB]. The encoded block format may optionally include an index that, during decoding, supports random access into a plurality of encoded blocks. Such a decoder can decode the encoded block format of the disclosed technology, thereby generating N decoded output values from each encoded input block, and wherein the regenerated (decoded) output values are identical to the encoder's original N data elements

Described is an encoded block format suitable for representing the contents of blocks (subsets) of digital data using fewer bits. The original data is divided into blocks that each contain Nb elements. The disclosed technology refers to such subsets as “input blocks of block size Nb,” Nb may remain fixed or may vary from block to block, depending on the application. Each encoded block contains a header and a payload. The header specifies the unique characteristics of elements used by the payload to describe single-Byte or multi-Byte events that occurred in the input block. The encoded block format is generated by one or more block-oriented encoders (compressors) that converts input blocks of Nb digital data elements into the disclosed technology's encoded block format, Blocks confirming to the disclosed technology's encoded block format may be consumed by one or more decoders (decompressors) that regenerate Nb elements from each decoded (uncompressed) block, using an encoded block representation as described herein. Each decoded block contains Nb regenerated elements that are identical to corresponding Nb elements of the original input block. Encoded blocks are typically smaller than the original input blocks they represent, thus delivering lower storage costs and faster transfers of digital data. In certain applications, the disclosed technology's block encoding format may optionally include an index that supports random access during decoding of a stream of encoded blocks.

### BRIEF DESCRIPTION OF THE DRAWINGS

FIG. 1a illustrates the operation of a prior art encoding method.

FIG. 1b illustrates a prior art single-Byte encoded event,

FIG. 1c illustrates a prior art multi-Byte encoded event.

FIG. 2a illustrates an input block of N input elements being divided into blocks of Nb elements.

FIG. 2b illustrates the encoding of an input block of Nb elements into the disclosed technology's encoded block format, and the subsequent decoding of an encoded block into a regenerated block of elements.

FIG. 2c illustrates an encoded header and an encoded payload of the disclosed technology.

FIG. 3 illustrates the disclosed technology's encoded block, which has a header portion and a payload portion, wherein the header portion further contains header subsets and the payload portion further contains payload subsets.

FIG. 4a illustrates a multi-Byte sequence event of the disclosed technology.

FIG. 4b illustrates a multi-Byte run event of the disclosed technology,

FIG. 4c illustrates a single-Byte literal event of the disclosed technology.

FIG. 5a illustrates four examples of the disclosed technology's single-Byte and multi-Byte events.

FIG. 5b illustrates example fields of an encoded sequence event of the disclosed technology.

FIG. 5c illustrates example fields of an encoded run event of the disclosed technology.

FIG. 5d illustrates example fields of an encoded literal event of the disclosed technology.

FIG. 5e illustrates example fields of an encoded dictionary event of the disclosed technology.

FIG. 6a illustrates example fields found in a sequence event header.

FIG. 6b illustrates an example of how unique sequence lengths might be mapped to their corresponding tokens and token lengths.

FIG. 6c illustrates an example of a series of sequence length tokens and sequence distances might be mapped into a sequence event payload.

FIG. 7a illustrates example fields found in a run length header.

FIG. 7h illustrates example fields found in a run value header.

FIG. 7c illustrates an example of how unique run lengths might be mapped to their corresponding tokens and token lengths.

FIG. 7d illustrates an example of a series of run length tokens and run value tokens might be mapped into a run event payload.

FIG. 8a illustrates an example of the fields found in a dictionary header.

FIG. 8b illustrates an example of how unique dictionary words might be stored in a dictionary header.

FIG. 8c illustrates an example of a series of dictionary references in a dictionary event payload.

FIG. 9a illustrates example fields found in a literals event header.

FIG. 9b illustrates an example of how unique single-Byte literals might be mapped to their corresponding tokens and token lengths.

FIG. 9c illustrates an example of how a series of literal events might be mapped to literal tokens and token lengths.

FIG. 10 illustrates an example of an encoder that encodes and input block of Nb elements into an encoded block with a header portion and a payload portion of the disclosed technology.

FIG. 11 illustrates an example of a decoder that regenerates a decoded block of elements from an encoded block with a header portion and a payload portion of the disclosed technology,

FIG. 12 illustrates how multiple, independent encoders can simultaneously generate a series of encoded blocks.

FIG. 13 illustrates how multiple, independent decoders can simultaneously generate a series of decoded blocks.

FIG. 14 illustrates an example of how an index of encoded block sizes might be generated.

FIG. 15a illustrates an example of how a random access specifier might converted to various block numbers, block counts, and Byte offsets,

FIG. 15b illustrates example code written in the C programming language that calculates certain variables used in FIG. 15a.

FIG. 16 illustrates an example of how the various block numbers, block counts, Byte offsets, and the index of encoded block sizes from FIGS. 14, 15a, and 15b might be used to provide random access into a stream of encoded blocks.

FIG. 17 illustrates example code written in the C programming language that advances a file pointer to the proper starting block for a decoder.

FIG. 18 illustrates example code written in the C programming language that controls the generation of NBytes uncompressed elements decoded from randomly accessed, encoded blocks.

FIG. 19a illustrates an example of unique literal event counts.

FIG. 19b illustrates the example token tables that might be used as tokens for the five unique literals found in FIG. 19a.

FIG. 19c illustrates how the table that minimizes the total number of bits required to represent the example literals and their counts in FIG. 19a.

FIG. 20a illustrates an example containing ten events to be encoded in a block.

FIG. 20b illustrates an example of the order in which FIG. 20a's ten example events might be sent,

FIG. 20c illustrates an alternate example of the order in which FIG. 20a's ten example events might be sent.

### DETAILED DESCRIPTION OF THE INVENTION

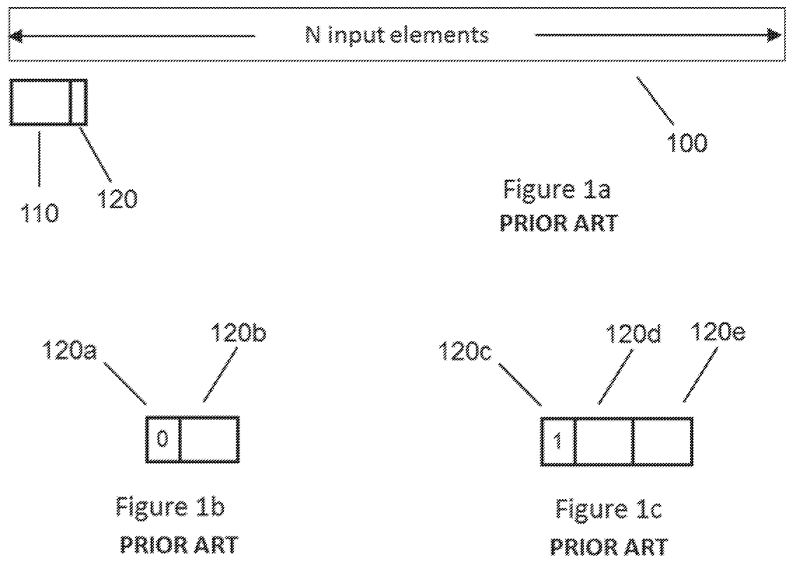

FIG. 1a [PRIOR ART] illustrates an encoding method that uses a sliding window to encode N input elements 100. Previously viewed data buffer 110 is treated as a buffer of previously seen elements (typically Bytes, where 1 Byte=8 bits). Each Byte of N input elements 100 could represent an encoded alphabetical letter, such as ‘A’ or ‘e’ using a common encoding method, such as ASCII encoding. A buffer 120 contains one or more Bytes that are not yet encoded. An encoding algorithm (not shown in FIG. 1a) determines the longest sequence of Bytes in buffer 120 that previously occurred in previously viewed data buffer 110. In most prior art encoders, a sequence in buffer 120 must match at least 3 Bytes found in previously viewed data buffer 110. The LZ-77 sliding window encoder is an example implementation of the prior art encoder illustrated in FIG. 1a.

Prior Art sliding window encoders typically distinguish between just two kinds of events: single-Byte events (which are expanded by 1 bit per single-Byte event), and multi-Byte events (which are compressed), As previously mentioned, multi-Byte events generated by prior art sliding window encoders must match 3 or more elements in previously viewed data buffer 110.

FIG. 1b [PRIOR ART] illustrates an example single-Byte event, with prefix 120a (a ‘0’ bit) and suffix 120b (typically the original 8-bit Byte being represented). FIG. 1c [PRIOR ART] illustrates an example multi-Byte event with prefix 120c (a ‘1’ bit), a distance field 120d, and a length field 120e, Distance field 120d specifies how far back in previously viewed data buffer 110 the example sequence begins. Length field 120e represents the number of elements (typically Bytes) to copy in order to regenerate the sequence found at that position in buffer 120.

Prior art encoders and decoders that utilize a sliding window suffer from the following drawbacks:
a) Sliding window encoders are hard to parallelize, and if parallelized, they require overlapping data to support parallel encoding, which increases memory requirements,
b) Sliding window decoders are hard or impossible to parallelize, because the meaning of encoded elements depends upon previously decoded elements that may or may not be present,
c) Sliding window decoders do not typically support random access into the encoded stream, but instead require the entire contents up to the desired “start of random access” location to be decoded before the desired subset of Bytes is returned. Such behavior makes random access into sliding-window-encoded data slow and difficult.

In contrast, the encoded block format of the disclosed technology, the encoders that generate the encoded block format, and the decoders that decode the encoded block format, were designed to overcome the drawbacks of prior art sliding window encoders and decoders listed above.

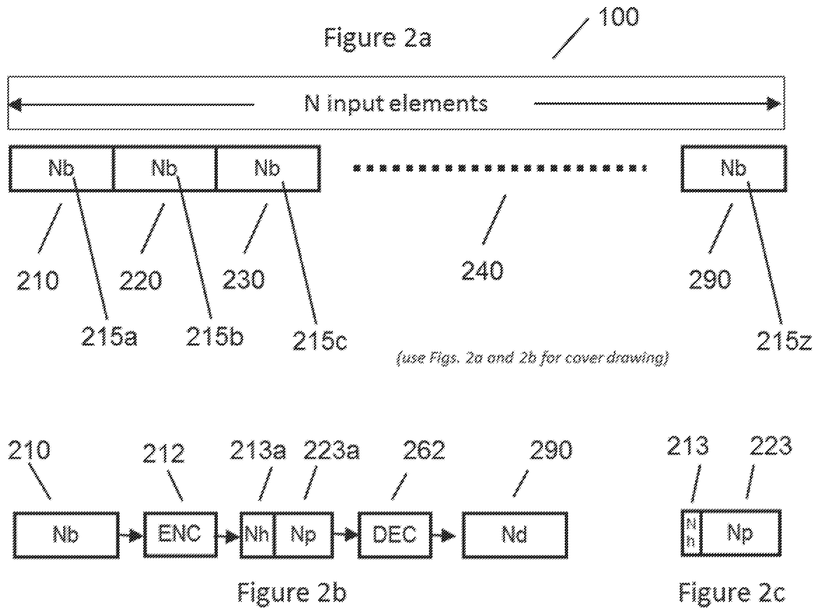

FIG. 2a illustrates how the disclosed technology first separates N input elements 100 (intended to represent the same N input elements 100 as in FIG. 1a) into blocks of Nb elements 215a . . . 215z. In a preferred embodiment, Nb for 215a, 215b, . . . 215z are identical, except that in the general case, the final block size 215z may contain fewer than Nb elements. For the remainder of this patent application, concatenated Block 1 210, Block 2 220, Block 3 230, etc. to final block 290 together contain all N input elements 100. In FIG. 2a, element count 215a=element count 215b=Nb. Element counts 215 represent the number of elements (typically Bytes) in Block 210, Block 220, etc., respectively.

FIG. 2b illustrates haw an encoder 212 encodes example Block 210 into encoded header 213a and encoded payload 223a, which represent the elements in Block 210 using fewer bits. Also shown in FIG. 2b, a decoder 262 decodes encoded header 213a and encoded payload 223a and re-creates decoded output block 290. Since the process of converting example Block 210 into encoded header 213a and encoded payload 223a and then decoding encoded header 213a and encoded payload 223a into decoded output block 290 is lossless, decoded output block 290 contains Nd=Nb elements that are identical to the Nb elements in Block 210.

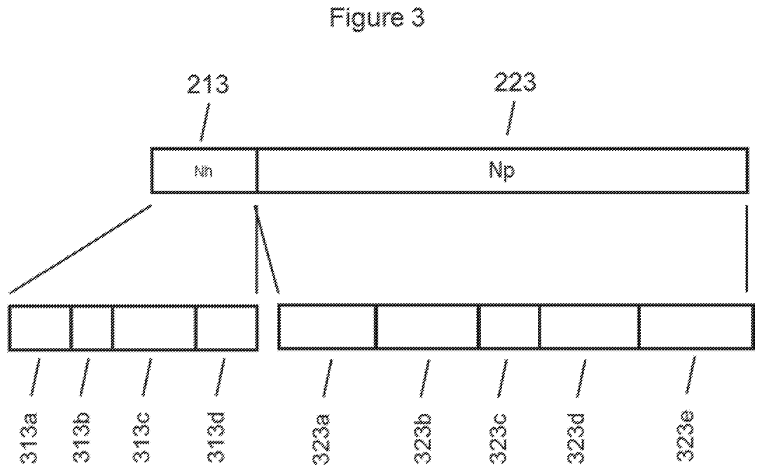

FIG. 2c illustrates the general structure of each output block of the disclosed technology, which contains encoded header 213 and encoded payload 223. Without diverging from the intent of this patent application, encoded header 213 and encoded payload 223 can be transmitted or stored in any order. Similarly, the various subsets of encoded header 213 and encoded payload 223 (further described in FIG. 3) can be stored or transmitted in any order, without diverging from the intent of this patent application.

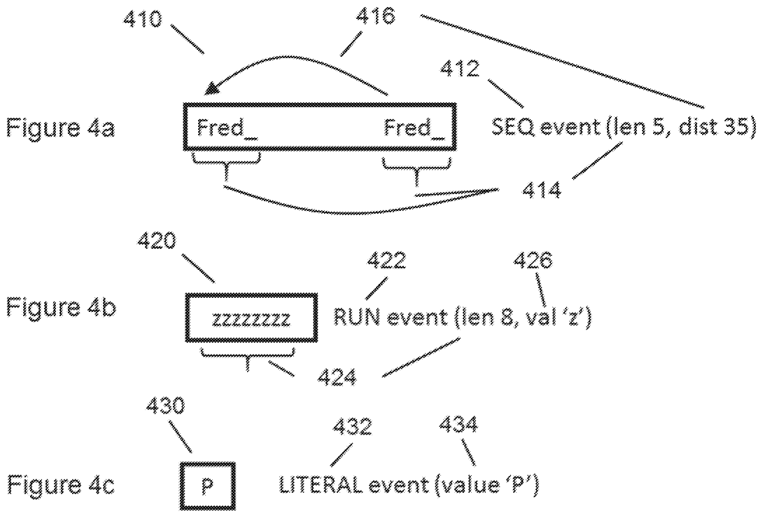

FIG. 3 further details that encoded header 213 contains encoded header element 313a, encoded header element 213b, etc. Similarly, FIG. 3 illustrates that encoded payload 223 contains encoded payload element 323a, encoded payload element 323b, etc. The number of encoded header elements 313 and encoded payload elements 323 need not be equal, since some types of encoding events (examples of such encoding events are provided in FIGS. 4-9) do not require corresponding header information, and some encoded header elements 313 may contain parameters or information that pertains to two or more encoded payload elements 323,

FIG. 4 provides examples (in FIGS. 4a and 4b) of two multi-Byte events and (in FIG. 4c) of a single-Byte event. FIG. 4a illustrates a sequence (SEQ) event 410. The disclosed technology represents the second sequence in sequence event pair 410 using three fields: a sequence event indicator 412, a sequence length 414 and a sequence distance 416. Similar to prior art compressors, sequence events are described by (length, distance) parameters, but the way that the disclosed technology encodes these parameters differs from how prior art compressors represent sequence events. In the example shown in FIG. 4a, the second occurrence of the length-5 (five Bytes) string ‘Fred_’ (where ‘_’ represents a space) is replaced by the three sequence event fields 412, 414, and 416. Sequence event indicator 412 is usually encoded using 1 or 2 bits, while sequence length 414 might be encoded using 2 to 6 bits in sequence length token 514. Similarly, sequence distance 416 is encoded in sequence distance field 516 using log₂(sequence location). The sum of the bits in fields 412, 514, and 5416 is always smaller than Nlen×8 bits, where Nlen is the sequence length 414, so the encoded representation of sequence event 410 (which is the concatenation of bits in 412, 514, and 516) occupies fewer bits than sequence event 410 did.

FIG. 4b illustrates a run event 420 that the disclosed technology represents using three fields: a run event indicator 422, a run length 424, and a run value 426. In the example shown in FIG. 4b, run event 420 contains eight ‘z’ letters in a row—a “run” of 8 z's, Run events consist of run event indicator 422, run length 424, and run value 426. As with sequence event 410, run event 420 contains Rlen Bytes length 424×8 bits per Byte), and the concatenation of elements 422, run length token 524, and run value token 526 occupies less bits that original run 420 did.

FIG. 4c illustrates an example of a single-Byte literal event 430 that contains the single Byte ‘P.’ The disclosed technology represents single-Byte literals using literal event indicator 432 followed by literal value 434.

In the three examples provided in FIG. 4, we note that certain event parameters, such as sequence lengths 414, run lengths 424, and literal values 434 take on values that are unique from block to block. For example, Block 210 in FIG. 2a may contain sequences having sequence lengths 414 of {2, 3, 5, 6, 14, 23, and 31} Bytes, while Block 220 in FIG. 2a may contain sequence lengths 414 of {2, 3, 4, 5, 8, 9, 10, 15, and 20} Bytes. Similarly, Block 210 may contain runs having run values 426 {‘e’, ‘5’, and ‘.’}, while Block 220 may contain runs having run values 426 of {‘e’, ‘.’, and ‘s’}.

As part of the encoding process of the disclosed technology, encoder 212 gathers and counts the unique events and parameters that are found in each block and encodes those unique events and parameters in one or more encoded header elements 313. Encoded payload elements 323 then describe events in that block using tokens and token lengths from each corresponding header that specify which of the unique elements described in the corresponding event's header occur at the location or locations where each event occurred in that block.

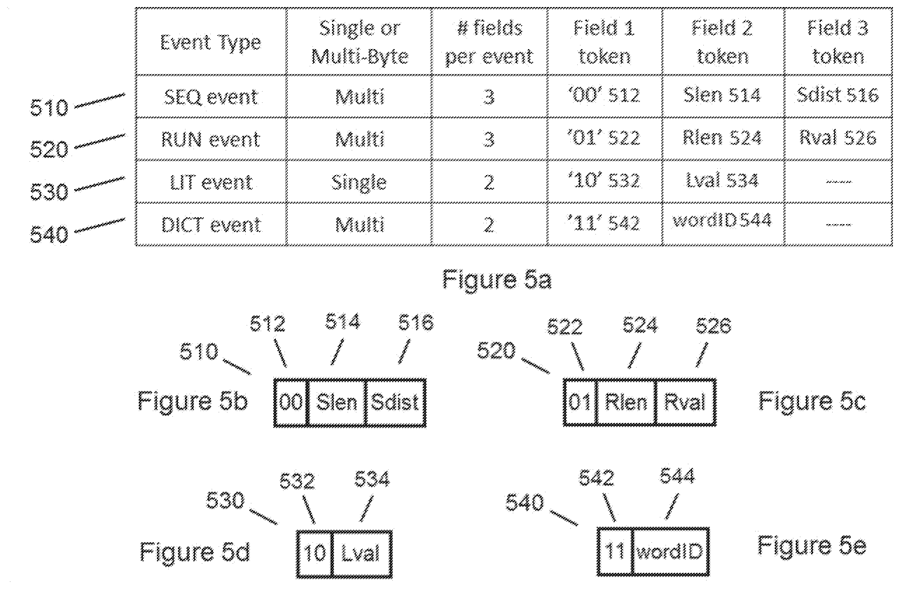

FIG. 5 provides additional details about the fields that comprise sequence events 410, run events 420, literal events 430, and dictionary events 440. Specifically, FIG. 5 provides examples of how certain parameters (such as sequence length 414 or run value 426) are replaced with corresponding, unique tokens (such as sequence length token 514 or run value token 526).

FIG. 5b and the five columns of FIG. 5a illustrate that sequence event bits 510:
a) Are multi-Byte events>1 Byte),
b) Contain 3 fields,
c) Field 1 contains the sequence event token 512 that uses the two bits ‘00’,
d) Field 2 contains the sequence length token bits 514 that represent sequence length 414,
e) Field 3 contains the sequence distance bits 516 that represent sequence distance 416,

FIG. 5c and the five columns of FIG. 5a illustrate that run event bits 520:
a) Are multi-Byte events (length>1 Byte),
b) Contain 3 fields,
c) Field 1 contains the run event token 522 that uses the two bits ‘01’
d) Field 2 contains the run length token 524 that represent run length 424,
e) Field 3 contains the run value token 526 that represent run value 426.

FIG. 5d and the five columns of FIG. 5a illustrate that literal event bits 530:
a) Are single-Byte events (length=1 Byte),
b) Contain 2 fields,
c) Field 1 contains the literal event token 532 that uses the two bits ‘10’,
d) Field 2 contains literal value token 534 that represents literal value 434.

FIG. 5e and the five columns of FIG. 5a illustrate that dictionary event bits 540:
a) Are multi-Byte events (length>1 Byte),
b) Contain 2 fields,
c) Field 1 contains the dictionary event token 542 that uses the two bits ‘11’,
d) Field 2 contains wordID token 544.

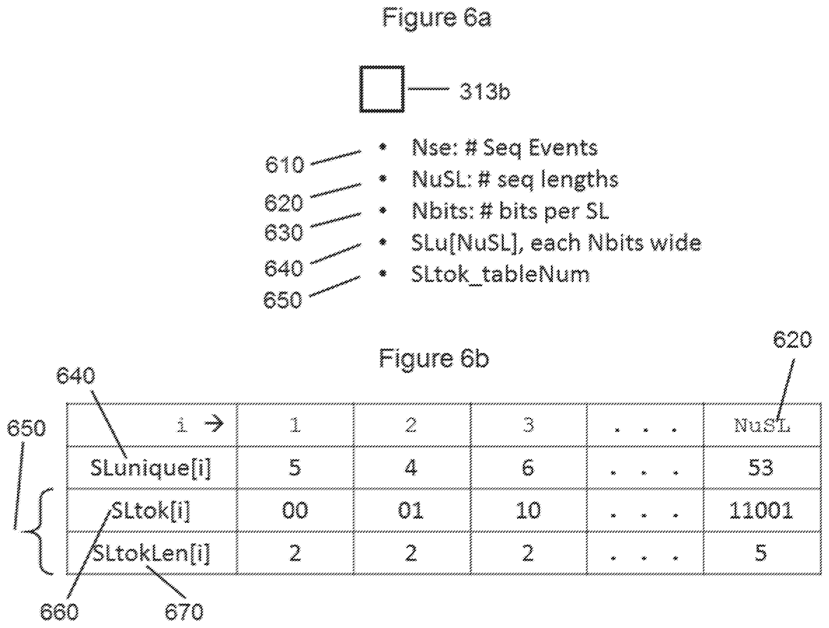

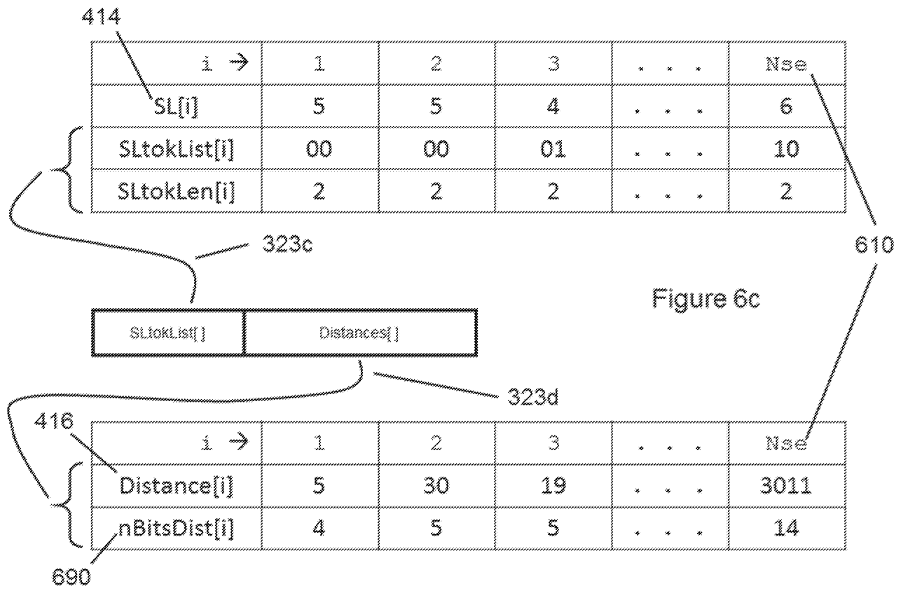

FIGS. 6-9 provide examples of how various lengths and values (such as sequence length token 414 and literal value token 434) are mapped to unique representations called tokens (such as sequence length token 514 and literal value token 534). The disclosed technology provides a mechanism using certain bits in header fields 313 whereby the disclosed technology's encoder 212 signals to the disclosed technology's decoder 262 such specific mappings between (for example) {lengths, values} and {length field tokens, value field tokens}.

Those familiar with compression will recognize that such parameter-to-token mappings are often performed to reduce the number of bits required to assign a fixed number of parameters (also signaled in block header 313) to specific tokens of varying width, such as the Huffman codes that are well-known to those familiar with compression techniques. In general, the mappings used by the disclosed technology assign shorter codes to frequently occurring parameters, and longer codes to less common parameters. By doing so, frequently occurring sequence lengths 410b and literal values 430b are assigned to sequence length fields 510 and literal value fields 530 whose field length is inversely proportional to the (length and value's) frequency of occurrence, Commonly occurring parameters use shorter codes, while less frequent parameters use longer codes.

FIGS. 6a, 6b, and 6c together illustrate examples of how example sequence event header 313b (in FIG. 6a) is used by the disclosed technology to define the sequence parameters used in sequence length payload 323c (in FIG. 6c) and sequence distance payload 323d (in FIG. 6c).

FIG. 6a illustrates an example of sequence event header 313b that contains five fields:
1, Nse: the number of sequence events 610 that appear in sequence length payload 323c and sequence distance payload 323d. Note that since every sequence event contains a (length, distance) pair that signals sequence length 414 and sequence distance 416 via sequence length token 514 and sequence distance field 516. Thus in FIG. 6c, the number of sequence length fields 610 in sequence length payload 323c and the number of sequence distance fields 610 in sequence distance payload 323d is identical. The number of bits in sequence length payload 323c and the number of bits in sequence distance payload 323d are not necessarily the same, since the mapping of sequence lengths 414 to sequence length tokens 514 likely differs from the mapping of sequence distances 416 to sequence distance fields 516. Similarly, the number of unique sequence lengths 620 is typically unrelated to the distance 416 where the previous sequence occurred.
2. MST: the number of unique sequence lengths 620 used in sequence length payload 323c. Note that the number of unique sequence lengths is a characteristic of a particular input block 210, 220, 230, etc. and typically varies from block to block,
3. Nbits: the number of bits 630 used by each entry in the array of unique sequence lengths 640.
4. SLu[ ]: an array of unique sequence lengths 640, each of which occupies Nbits 630 bits. In a preferred embodiment, elements of the array of unique sequence lengths 640 are listed in decreasing frequency order. Thus the first entry in unique sequence length array 640 is the most frequently occurring sequence length in the current block, and the last entry in unique sequence length array 640 is the least common sequence length in the current block.
5. SLtok_tableNum: a sequence length mapping identifier 650 that maps each unique sequence length array value 640 to a specific (predetermined) {token, token length} pair, selected from a predetermined number of token tables.

FIG. 6b provides an example of how unique sequence length array 640 is mapped via mapping identifier 650 to a particular list of {sequence length token 660, sequence length token length 670} pairs. FIG. 6b illustrates that this example contains unique sequence length array 640 (SL[i]) contains NuSL number of unique sequence lengths 620. In the example in FIG. 6b, sequence lengths 5, 4, and 6 occur frequently (and are thus assigned sequence length tokens 660 ‘00’, ‘01’, and ‘10’ respectively, each having token lengths 670 of 2 bits), while sequence length 53 is rare, perhaps occurring just once in input block 210. Because sequence length 53 is rare, it is assigned a token ‘11001’ having a token length 670 of 5 bits, Thus in this example, common sequence lengths are assigned short tokens of 2 bits, while rare sequence lengths are assigned longer tokens of 5 bits.

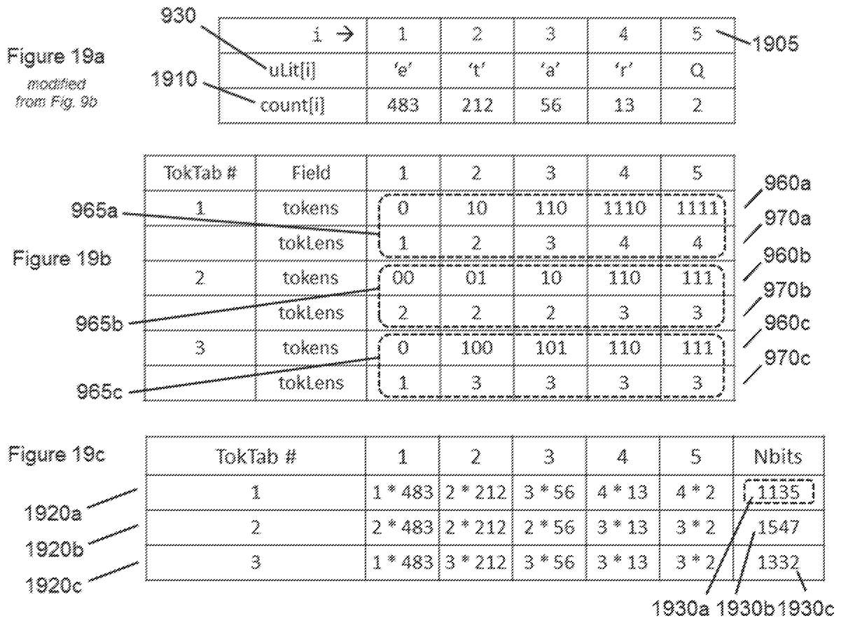

Encoder 212 selects from among multiple, predetermined tables of {token 660, token length 670} pairs, based on the table that minimizes the number of bits required to represent the number of sequence events 610 encoded in sequence length payload 323c, as further described in FIG. 19.

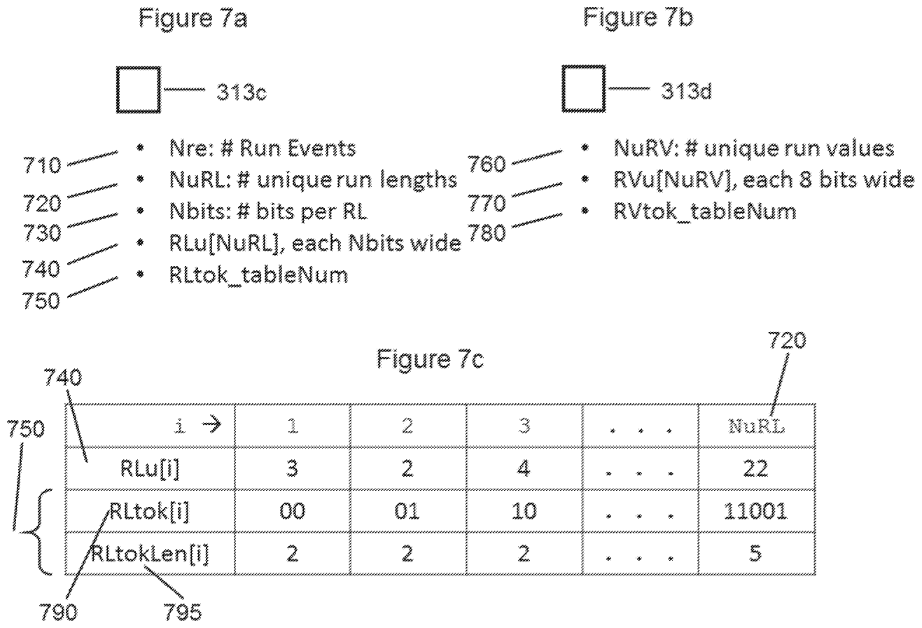

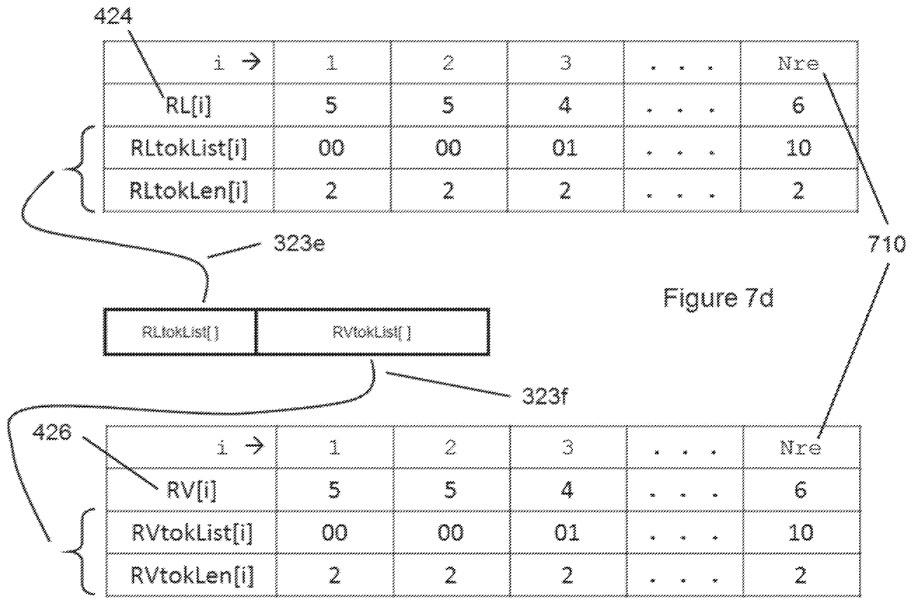

By providing both unique sequence length array 640 and mapping identifier 650, sequence length header 313b is able to signal to decoder 262 the mapping between each entry of unique sequence length array 640 and its corresponding {token 660, token length 670} pair. Because encoder 212 selects from among a limited number of mapping tables (frequencies of occurrence of unique multi-Byte and single-Byte parameters), encoder 212 is also able to re-use mapping identifiers 650 for all parameters (sequence lengths 410b, run values 420c, literal values 420c, etc.). Thus mapping identifier 650 described with FIG. 6 will be re-used again in the following discussions related to FIGS. 7, 8, and 9. Although the parameters being encoded vary from figure to figure, the “shapes” are chosen by encoder 212 to match the “shape” (distribution) of each parameter being encoded, chosen from among a limited number of available mapping “shapes.”

Once example sequence header 313b has signaled the five parameters of sequence events 410 described in FIG. 6a, FIG. 6c illustrates how encoder 212 maps sequence lengths 680 (of which there are Nse number of sequence events 610) to their corresponding {token 660, token length 670} pair. Given the mapping between unique sequence length array 640 and its corresponding {token 660, token length 670}, encoder 212 performs the following three steps for each of Nse 610 sequence lengths in sequence length array 410h:
a) Fetch the current sequence length 414 SL[i],
b) Map the current sequence length 414 SL[i] to its corresponding, unique {token 660, token length 670} from FIG. 6b,
c) Pack the current sequence length's unique {token 650, token length 670} from FIG. 6b into sequence length payload 323c.

In the example shown in FIGS. 6b and 6c, note that unique sequence lengths {4, 5, 6} are always mapped to the tokens {01, 00, 10} that use {2, 2, 2} bits as their token length. This mapping was defined for all unique sequence lengths in the block, as shown in FIG. 6b.

FIG. 6c also illustrates an example of how Nse unique sequence distances 610 are encoded into sequence distance payload 323d. Because the length of all sequence events is known after decoder 262 has decoded sequence length payload 323c, the starting location of each sequence is also known, so the number of bits per distance parameter 690 is also known.

For example, with Nb=4096 (4096 Bytes per Block 210, 220, etc.), sequence events 410 that begin at Byte offsets 0 . . . 15, by definition, have distances that will fit into 4 bits, because ceil(log₂[15])=4. In other words, each sequence's distance cannot be larger than the location in the block where the sequence begins: if a sequence begins at location 597, there are only 596 possible locations where the previous (matching) sequence can begin, so the distance for that sequence will implicitly be encoded using log 2(597)=10 bits.

In a similar manner, sequence events that begin at Byte offsets 1024 . . . 2047, will use 11-bit distances, because ceil(log₂[2047])=11. Thus the disclosed technology's sequence distance payload implicitly encodes the number of bits per distance parameter 690, because both encoder 212 and decoder 262 are aware of the starting location of each sequence event. FIG. 6c illustrates the implicit mapping of sequence distances 410c and the number of bits per sequence distance 690 as the distance bits in this example are packed into distance payload 323d.

FIGS. 7a thru 7d provide an example of how the disclosed technology encodes run events 420. In a manner analogous to that described in FIG. 6a, FIG. 7a provides an example in which run event header 313c contains the following five fields:
1. Nre: the number of run events 710 represented in FIG. 7d's run length payload 323e and run value payload 323f. As previously described in FIG. 4b, every run event is described using a (length, value) pair that specifies run length 410b and run value 420c via run length tokens 524 and run value tokens 526 (FIG. 5c). Thus in FIG. 7d, the number of run length tokens 524 in run length payload 323e and the number of run value tokens 526 in sequence distance payload 323f are identical to Nre number of run events 710. The number of bits in run length payload 323e and the number of bits in run value payload 323f are not necessarily the same, since the mapping of run lengths 424 to run length tokens 524 likely differs from the mapping of run values 426 to run value tokens 526. Similarly, the number of unique run lengths 720 (FIG. 7a) is typically unrelated to the number of unique run values 760 (FIG. 7b),
2. NuRL: the number of unique run lengths 720 appearing in run length payload 323e. Note that the number of unique run lengths is a characteristic of a particular input block 210, 220, 230, etc. and typically varies from block to block.
3, Nbits: the number of bits 730 used by each run length entry in the array of unique run lengths 740, RLu[ ].
4. RLu[ ]: an array of unique run lengths 740, each of which occupies Nbits 730 bits. In a preferred embodiment, elements of the array of unique run lengths 740 are listed in decreasing frequency order. Thus the first entry in unique run length array 740 is the most frequently occurring run length in the current block, and the last entry in unique run length array 740 is the least common run length in the current block.
5. RLtok_tableNum: a run length mapping identifier 750 that maps each unique run length 740 to a specific (predetermined) {run length token 790, run length token length 795} pair, selected from a predetermined number of tables.

FIG. 7b shows an example run value header 313d that contains three fields:
1. NuRV: the number of unique run values 760 occurring in run value payload. 323f. Note that the number of unique run values is a characteristic of a particular input block 210, 220, 230, etc. and typically varies from block to block.
2. RVi[ ]: an array of unique run values 770, each of which occupies 8 bits, because all run values are Bytes in the range 0 . . . 255. In a preferred embodiment, elements of the array of unique run values 770 are listed in decreasing frequency order. Thus the first entry in unique run value array 770 is the most frequently occurring run value in the current block, and the last entry in unique run value array 770 is the least frequently occurring run value in the current block.
3. RVtok_tableNum: a mapping identifier 780 that maps the distribution of unique run value array values 770 to a specific (predetermined) {token, token length} pair, selected from a predetermined number of tables.

FIG. 7c provides an example of how unique run length array 740 could be mapped via run length mapping identifier 750 to a particular list of {token 790, token length 795} pairs. FIG. 7c illustrates that unique run length array 740 (RL[i]) contains NuRL number of unique run lengths 720. In the example in FIG. 7c, run lengths 3, 2, and 4 occur frequently and are thus assigned sequence length tokens 790 having token lengths 795 of 2 bits. In contrast, run length 22 is rare, perhaps occurring just once in the current block, Thus the rare run length with value 22 is assigned a token ‘11001’ having a token length 795 of 5 bits.

In a manner similar to that previously used with FIG. 6c, FIG. 7d illustrates how run lengths 424 are mapped using the {token 790, token length 795} to the run length tokens 790 that are packed into run length payload 323e. Similarly, FIG. 7d also illustrates how run value tokens 526 are mapped to tokens (not shown in FIG. 7) representing run value 426. These tokens 526 are packed into run value payload 323f,

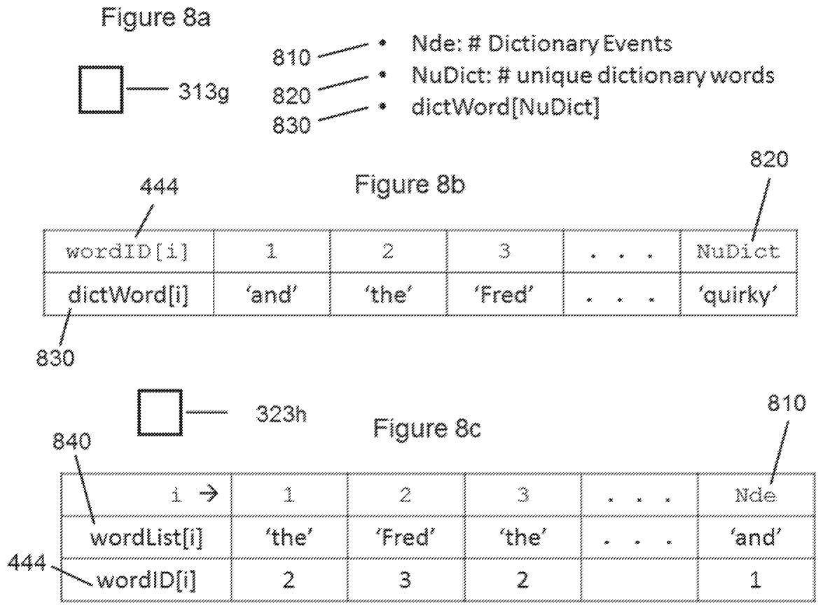

FIG. 8 illustrates another type of multi-Byte event called a dictionary event. Dictionary events are repeated, frequently occurring multi-Byte events (“words”) in the current block. As shown in FIG. 8c, dictionary words 830 are represented with their corresponding word ID 444. By using dictionary encoding, the disclosed technology's encoded block format achieves significant compression when input blocks contains repeated multi-Byte events. In FIG. 8a, dictionary header 313g contains three fields:
1. Nde: the number of dictionary events 810 in the current block,
2. NuDict: the number of unique dictionary words 820 in the current block,
3. dictWord[NuDict]: an array of unique dictionary words 830, where each character of each dictionary word occupies 8 bits, since all dictionary words are composed of Bytes in the range 0 . . . 255. In a preferred embodiment, words of dictWord array 830 are listed in decreasing frequency order. Thus the first unique dictionary word 830 is the most frequently occurring multi-Byte dictionary word in the current block, and the last entry in dictWord array 830 is the least common multi-Byte dictionary word in the current block,

FIG. 8b illustrates an example array of unique dictionary words 830, where the first word is ‘and’ (3 letters), the second dictionary word is ‘the’ (3 letters), the third word is ‘Fred’ (4 letters), and the final Ndict 820'th word is ‘quirky’ (6 letters), The wordID 444 corresponding to each dictionary word 830 is also shown in FIG. 8b.

FIG. 8c illustrates an example word list 840 containing Nde dictionary events 810, and the replacement of each word list 840 event with its corresponding dictionary word ID 850, For instance, the first and third words on word list 440 are ‘the’, so the first and third words are represented by word. ID 444=2, since (as previously described with FIG. 2) unique dictionary word ‘the’ has word ID 444=2.

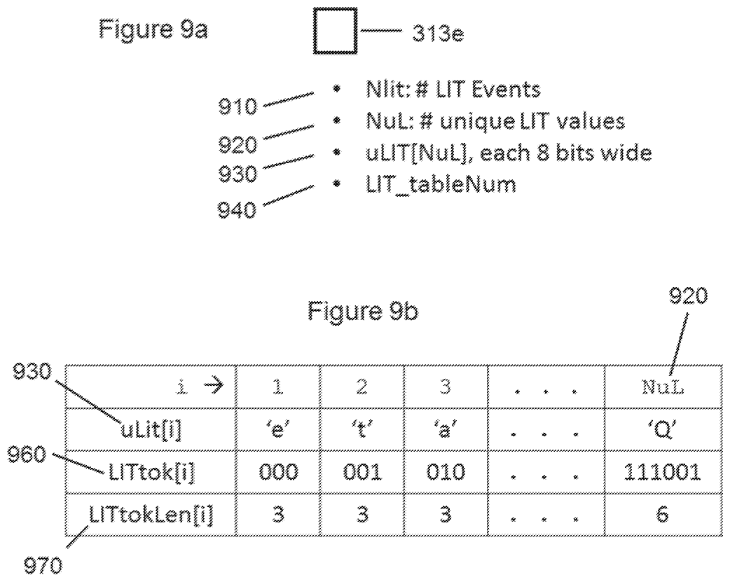

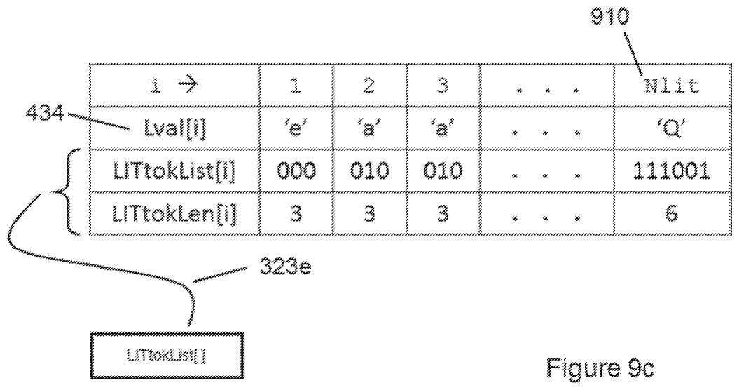

FIGS. 9a, 9b, and 9c illustrate how the disclosed technology combines literal event header 313e with literal event payload 323e to represent all literal (single-Byte) events in a block. In FIG. 9a, dictionary header 313e contains four fields:
1, Nlit: the number of literal (single-Byte) events 910 in the current block.
2. NuL: the number of unique literals 920 in the current block.
3. uLit[NuL]: an array of unique literals array 930, where each literal occupies 8 bits. In a preferred embodiment, literals in uLit array 930 are listed in decreasing frequency order.
4. LIT_tableNum: a literals mapping identifier 940 that maps each entry of unique literals array 930 to a specific (predetermined) {literals token 960, literals token length 970} pair, selected from a predetermined number of tables.

FIG. 9b illustrates an example mapping between the entries of unique literals array 940 and the {literals token 960, literals token length 970} pairs contained in the table specified by LIT_tableNum mapping identifier 940.

In a manner similar to that previously used with the description of FIG. 7d, FIG. 9c illustrates how literals entries 950 are mapped using the {literals token 960, literals token length 970} pairs 940 to the bits that are packed into literals payload 323e. For example, the second and third literal entries 950 representing the literal ‘a’ (in FIG. 9b) is replaced with {literals token 960, literals token length 9701 ‘010’, 3} from FIG. 9b. Similarly, the last literal entry 950, LVal[Nlit], is ‘Q’, so the literal ‘Q’ is replaced with {literals token 960, literals token length 970}={‘111011’, 6} from FIG. 9b.

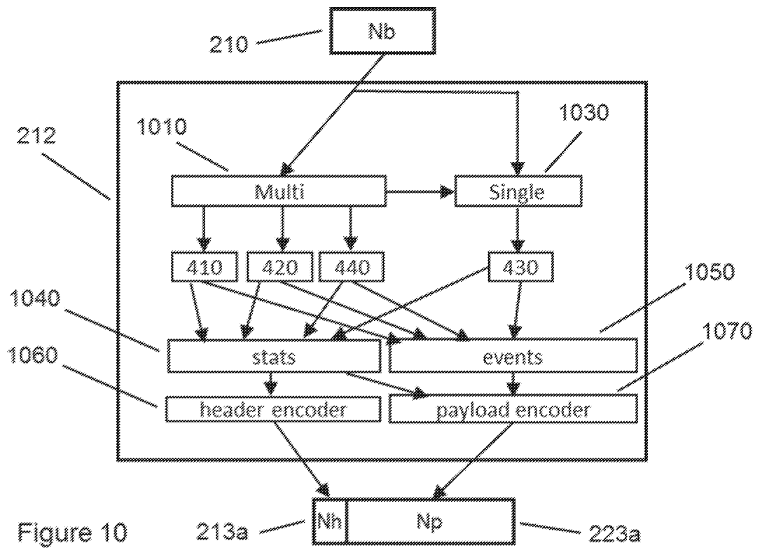

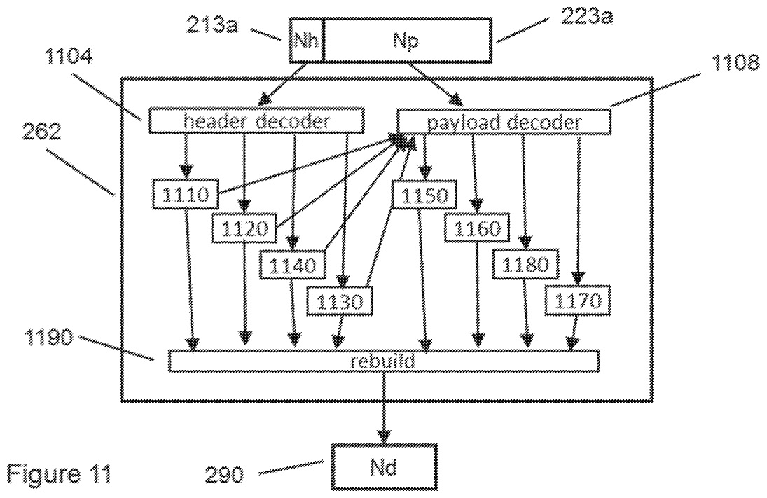

The technology described herein is embodied in data processing and communication systems that include encoders and decoders as described with reference to FIG. 10 and FIG. 11. Such systems comprise a processor including memory and a communication interface, configured to receive a file or stream including a plurality of input digital values, and execute lossless compression as described herein to generate a corresponding plurality of encoded blocks, and configured to store in the memory or transmit on the communication interface, the corresponding plurality of encoded blocks, wherein the corresponding plurality of encoded blocks is encoded without loss of data, and contains a sum of bits smaller than a sum of bits of the plurality of input blocks. The processor can be a computer program executing processor, or special purpose logic, or a combination of computer program executing and special purpose logic. Also, such systems can be configured to receive a plurality of encoded blocks, and execute lossless depression as described herein to generate a corresponding file or stream including a plurality of input digital values, and configured to store in the memory or transmit on the communication interface, the decoded file or stream including a plurality of input digital values, wherein the corresponding plurality of encoded blocks is decoded without loss of data.

FIG. 10 illustrates an example encoder 212 that generates the disclosed technology's encoded block format. Input block 210 is input to encoder 212, which outputs encoded header 213a and encoded payload 223a. Encoder 212 first scans all elements of input block 210 using multi-Byte detector block 1010, which identifies zero or more multi-Byte events in the block. Examples of multi-Byte events are sequence event 410, run event 420, and dictionary event 440. After all multi-Byte events are identified, a single-Byte event identifier 1030 identifies any remaining single Bytes not belonging to a multi-Byte event. All multi-Byte events and single-Byte events are then submitted to statistics block 1040, which identifies the unique multi-Byte parameters, such as unique sequence lengths 414, unique run lengths 424, etc., and the unique literals 434, as well as calculating various counts, such as the number of multi-Byte and single-Byte events, the number of unique parameters for multi-Byte and single-Byte events, etc.

As previously described in FIGS. 6-9, values describing unique parameters and their corresponding tokens are then combined by header encoder 1060, which, in a preferred embodiment, concatenates all headers 213. Similarly, multi-Byte and single-Byte events are encoded sequentially by combining the output of event list generator 1050 and the output of statistics block 1040. Header encoder 1060 generates the encoded header 213a, while payload encoder 1070 generates encoded payload 223a, which are combined to create an encoded block of the disclosed technology.

FIG. 11 illustrates how decoder 262 decodes example encoded header 213a and example encoded payload 223a, generating a decoded block 290. Header decoder 1104 decodes each of the header fields in encoded header 213a, which in the example of FIG. 11 consist of multi-Byte header A 1110, multi-Byte header B 1120, single-Byte header C 1140, and multi-Byte header D 1130. Payload decoder 1108 decodes each of the payload fields in encoded payload 223a, which consist (in the example of FIG. 11) of multi-Byte Payload A 1150, multi-Byte payload B 1160, single-Byte payload C 1180, and multi-Byte Payload D 1170. Payload decoder 1108 uses the decoded header fields 1110, 1120, 1140, and 11320 to decode the respective payloads 1150, 1160, 1180, and 1170. Rebuild block 1190 combines the unique parameters from decoded headers 1110, 1120, 1140, and 1130 and the decoded payloads 1150, 1160, 1180, and 1170 to create decoded block 290.

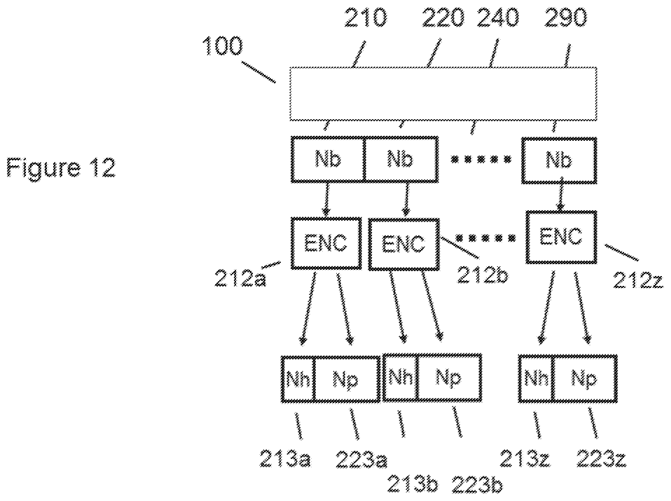

FIG. 12 illustrates how a plurality of simultaneously (concurrently) operating encoders 212a thru 212z encode the elements of input array 100, which is divided into a plurality of input blocks 210, 220, 240, etc., where in a preferred embodiment, each input block to encoders 212a thru 212z encoded an equal number of elements. Encoder 212a generates encoded block header 213a and encoded block payload 223a, while encoder 212b generates encoded block header 213b and encoded block payload 223b, and so on. Using Nx simultaneous encoders (Nx is not shown in FIG. 12), the encoding of input array 100 will operate Nx times faster than a single encoder 212 could encode input array 100. The Nx simultaneous encoders could be implemented using simultaneous (concurrent) software threads or simultaneous (concurrent) hardware blocks.

In many data centers, servers are not fully loaded (utilized), and thus concurrent software threads are usually available. Thus multiple encoded blocks of the disclosed technology can be encoded by multiple encoders to accelerate the encoding of input array 100. Similarly, multiple hardware blocks conforming to encoder 212 described in FIG. 10 could be instantiated in a system-on-chip (SoC) or application-specific integrated circuit (ASIC) to accelerate the hardware encoding of elements of input array 100.

Unlike prior art compression algorithms that use a sliding window, which are hard to parallelize, the disclosed technology's encoders 212 are what is known to those skilled in the art of distributed processing as “embarrassingly parallel,” meaning that if Nx times more processors (software threads or hardware instantiations) are available, the compression method of the disclosed technology will operate Nx faster than if just one encoder 212 were used. The linear relationship between the number of processors Nx and the resulting speed-up Nx defines the term “embarrassingly parallel.”

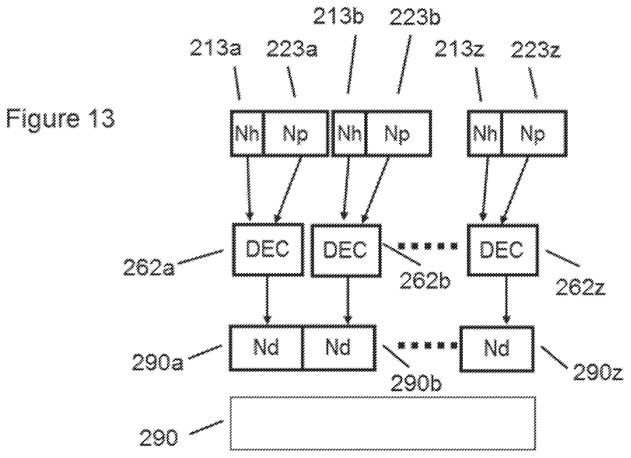

FIG. 13 illustrates how a plurality of simultaneously (concurrently) operating decoders 262a thru 262z decode a plurality of {encoded headers 213, encoded payloads 223} blocks, regenerating a plurality of decoded blocks 290a film 290z in the example shown in FIG. 13. Decoded blocks 290a thru 290z are typically concatenated to create final decoded output array 290.

In many data centers, servers are not fully loaded (utilized), and thus concurrent software threads are usually available. Thus multiple encoded blocks {213a, 223a}, {213b, 223b}, etc., of the disclosed technology can be decoded by multiple decoders 262 to generate a plurality of decoded blocks 290a thru 290z. Similarly, multiple hardware blocks conforming to decoder 262 described in FIG. 11 could be instantiated in a system-on-chip (SoC) or application-specific integrated circuit (ASIC) to accelerate the hardware decoding of elements of the plurality of encoded blocks {213, 223}.

Unlike prior art decompression algorithms that use a sliding window, which are hard or impossible to parallelize, the disclosed technology's decoders are what is known to those skilled in the art of distributed processing as “embarrassingly parallel,” meaning that if Nx times more processors (software threads or hardware instantiations) are available for decoding, the decompression method of the disclosed technology will operate Nx faster than if just one decoder 262 were used. The linear relationship between the number of processors Nx and the resulting speed-up Nx is what defines the term “embarrassingly parallel.”

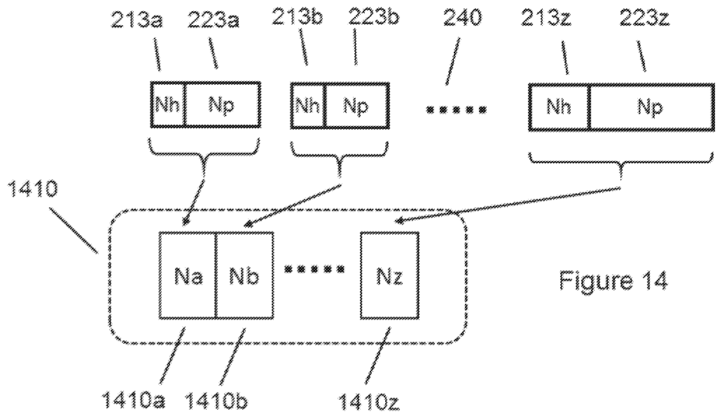

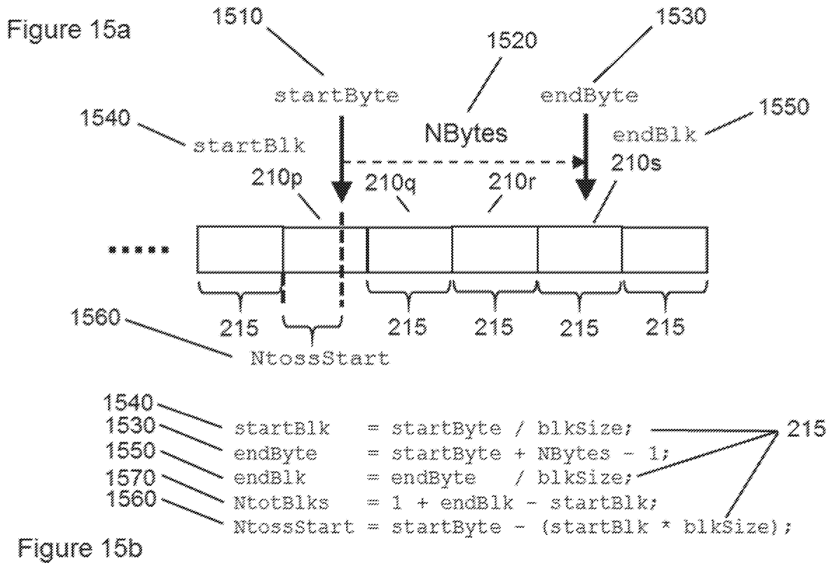

FIG. 14 illustrates the optional creation of a group of indexes 1410 during encoding that can be used during decoding to provide random access into a plurality of encoded blocks of the disclosed technology. FIG. 14 illustrates multiple encoded block pairs {header 213a, payload 223a}, {header 213b, payload 223b} thru {header 213z, payload 223z}. The number of bits, Bytes, or double words (dwords, or 32-bit words) in each of the encoded block pairs represents the size of the encoded block. In a preferred embodiment, the size of each encoded {header, payload} pair 213 is stored in index 1410 as a dword (4 Bytes). For instance, the number of dwords in encoded block {header 213a, payload 223a} is index entry Na 1410a, while the number of dwords in encoded block {header 213b, payload 223b} is index entry Nb 1410b. Once index 1410 has been created, FIGS. 15-18 below further describe how elements of index 1410 can be used to provide random access during decoding to a specific start location and number of elements. Random access is a feature that prior art encoders and decoders do not typically support because of their previously described difficulties in randomly accessing the encoded output of sliding window encoders.

FIGS. 15-18 describe a user-specified random access specifier in the form {startByte, NBytes} where both startByte and NBytes refer to the original, uncompressed elements (typically Bytes) that are requested from the original input to the encoder that generated encoded blocks conforming to the encoded block format of the disclosed technology. An equally useful, equivalent random access specifier may also have the form {startByte, endByte} where endByte=startByte+NBytes−1. These two random access specifiers are equivalent and interchangeable. Either one can be used to specify which decoded elements the disclosed technology returns to the user. For the examples provided in FIGS. 15-18 below, we assume that a random access specifier of the form {startByte, NBytes} will be used.

FIG. 15a illustrates how a user-specified {startByte 1510, NBytes 1520} random access specifier is converted into three random-access parameters {startBlk 1540, endBlock 1550, and NtossStart 1560}. In order to avoid having to decode all elements of a stream of encoded block that precede desired startByte 1510) the disclosed technology's group of indexes 1410 can be used to begin decoding of the encoded block that contains startByte 1510. A decoder that supports decoding of the disclosed technology's encoded blocks need only decode NtotBlocks 1570 in order to return the user-specified NBytes 1520.

As shown in the example of FIG. 15a, startByte 1510 is located in encoded block 210p, In a preferred embodiment of the disclosed technology, block size 215 is equal for all input blocks, so startBlk 1540 is determined by dividing startByte 1510 by block size 215. Similarly, the last block to be decoded by the decoder is endBlk 1550, calculated by dividing endByte 1530 by block size 215. endByte 1530 is the sum of startByte 1510 and Nbytes 1520, minus one. The total number of blocks NtotBlks 1570 to be decoded is one plus the difference between endBlk 1550 and startBlk 1540. Since startByte 1510 does not necessarily correspond to the first decoded element of block 210p (startBlk 1540), the variable NtossStart 1560 specifies how many elements (typically Bytes) of the first block will be “tossed” (discarded) prior to returning the NBytes 1520 that the user requested in {startByte 1510, NBytes 1520} random access specifier.

Using the C programming language, FIG. 15b illustrates example calculations (performed by decoder 262) of startBlk 1540, endByte 1530, endBlk 1550, NtotBlks 1570, and NtossStart 1560, in the manner consistent with the parameters discussed with FIG. 15a,

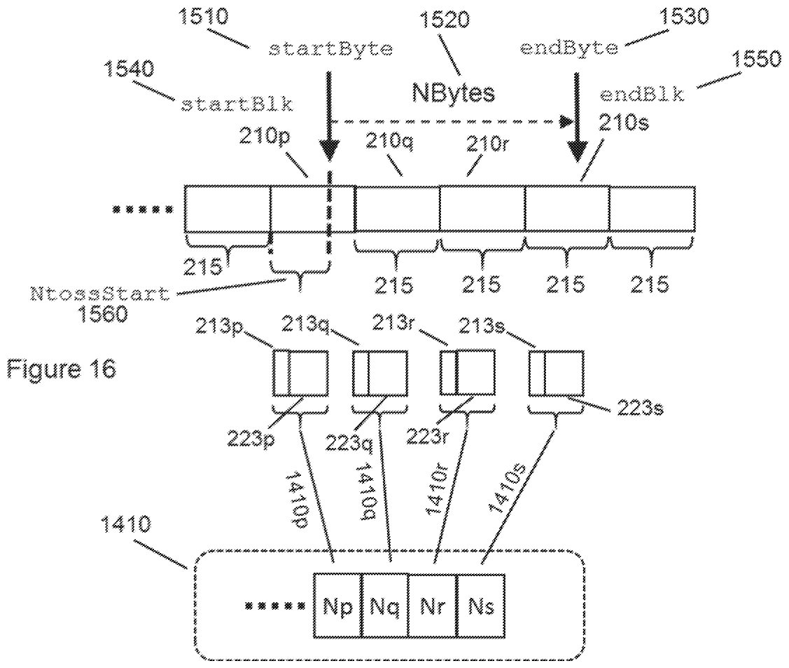

FIG. 16 illustrates additional details relating the original, uncompressed input blocks 210p, 210q, etc., each containing block size 215 samples, and their respective encoded block headers 213 and payloads 223. Specifically, encoder 212 converts the block size 215 elements of input block 210p into the encoded pair {encoded block header 213p, encoded block payload 223p}. In a similar manner, encoder 212 converts elements of input blocks 210q, 210r, and 210s into encoded pairs {encoded block header 213q, encoded block payload 223q}, {encoded block header 213r, encoded block payload 223r}, and {encoded block header 213s, encoded block payload 223s}, respectively. In the example of FIG. 16, the four encoded block pairs {213p, 223p} thru {2135, 223s} have sizes Np 1410p, Nq 1410q, Nr 1410r, and Ns 1410s, respectively. These four example block sizes Np 1410p thru Ns 1410s represent four of the elements in index 1410 of the disclosed technology.

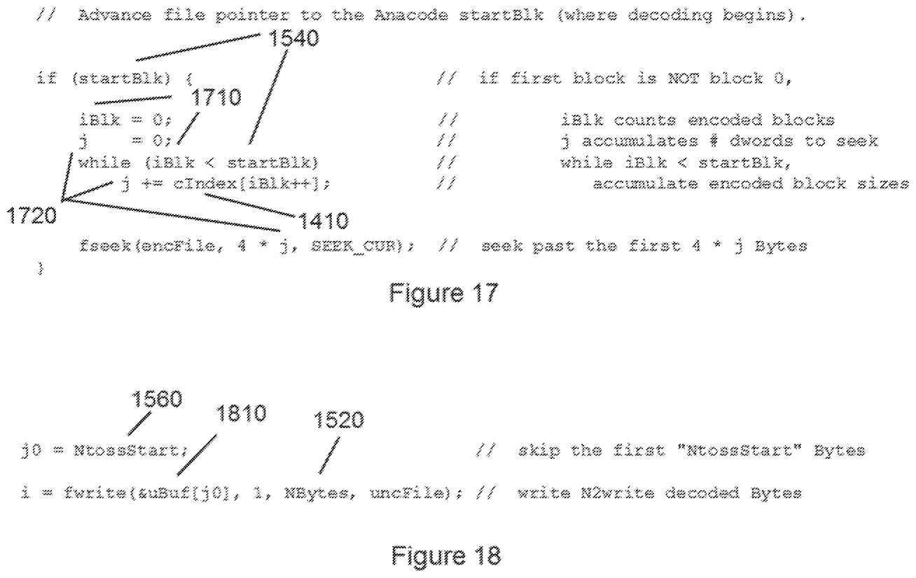

In response to a random access request, FIG. 17 illustrates how the first block to be decoded (startBlk 1540) is determined by decoder 262. If startBlk 1540 is not zero, a block counter iBlk 1710 and a dword seek counter j 1720 are initialized to zero. The “while” loop in FIG. 17 accumulates entries index 1410 encoded block sizes until the desired startBlk 1540 is found. The “fseek” function locates the start of encoded block startBlk 1540 by seeking 4*j Bytes. Since j is a double word [4-Byte] count, the seek distance is 4*j Bytes into the encoded file. After completing the programmed instructions in the example of FIG. 17, the file pointer into the file that contains the encoded blocks will be positioned at the start of startBlk 1540.

FIG. 18 illustrates how, after decoding NtotBlks 1570 encoded blocks, the total number of decoded elements generated by decoder 262 are processed to reflect NtossStart 1560. In the event that NtossStart 1560 (calculated as shown in FIGS. 15a and 15b) is greater than zero, the random access decoding operation by decoder 262 must “toss” (discard) the first NtossStart 1560 elements (typically Bytes) from uncompressed buffer uBuf 1810. Random access specifier {startByte, NBytes} and the calculations previously described in FIGS. 15-16 result in elements (typically Bytes) from uBuf[NtossStart] to uBuf[NtossStart+NBytes−1] being returned to the function that requested the random access decoding. In the example in FIG. 18, the desired NBytes 1520 are returned using a file write operation, where the first Byte returned is uBuf[j0] (=uBuf[NtossStart]), and where the file write operation writes NBytes 1520 Bytes to the file containing the decoded output elements from decoder 262.

FIG. 19 provides an example that demonstrates how one of three token tables is selected for the count distribution for five literals in an example block. This example demonstrates the calculations that determine which of the available token tables encodes the list of events using the fewest bits. Since the goal of compression is to minimize the number of bits used to encode certain events, selecting the table having the best {token 960, token length 970} pairs that minimize the number of bits required to encode parameters related to those events also maximizes the block's resulting compression ratio for those event parameters.

FIG. 19a illustrates an example unique literals array 930. In this example, the number of unique literals 1905 is five (5), but selecting the table that requires the minimum number of bits for encoding uses the same procedures, regardless of the number of unique literals 1905. FIG. 19a also illustrates the literals counts array 1910. Literals array 930 contains the five literal Bytes {‘e’, ‘t’, ‘a’, ‘r’, and ‘Q’}, whose corresponding literals counts array 1910 is {483, 212, 56, 13, and 2}. For example, the literal ‘e’ occurs 483 times in the block, while the letter ‘Q’ appears twice in the block.

FIG. 19b illustrates three token tables {965a, 965b, 965c}, each having a different set of five pairs of {token 960, token length 970}. Token table 1 965a contains binary tokens 960a {0, 10, 110, 1110, 1111}, with corresponding token lengths 970a of {1, 2, 3, 4, 4}. Token table 2 965b contains binary tokens 960b {00, 01, 10, 1110, 111}, with corresponding token lengths 970b of {2, 2, 2, 3, 3}. Token table 1 965c contains binary tokens 960c {0, 100, 101, 110, 111}, with corresponding token lengths 970c of {1, 3, 3, 3, 3}. Those skilled in the art of data compression will recognize that tokens {960a, 960b, 960c} are uniquely decipherable, meaning that no valid token is the prefix of another valid token. The example of FIG. 19b uses three candidate token tables 965a, 965b, and 965c, but selecting the “best” table (the one that encodes the selected event parameters using the fewest bits) uses the same procedures described for this example, regardless of the number of candidate token tables.

FIG. 19c illustrates how the total encoded bit counts 1930 of the three candidate token tables are calculated, given the literals count array 1910 of FIG. 19a. For each candidate token table, the number of bits Nbits[tokTab] used is calculated by the following C code:

for (tokTab = 1; tokTab <= 3; tokTab++) {

Nbits[tokTab] = 0;
for (i = 0; i < 5; i++) {

Nbits[tokTab] += sum(count[i]* tokLen[i]);

}

}

As illustrated in FIG. 19c, the Nbits array contains values {1930a, 1930b, 1930c)={1135, 1547, 1332} bits, Since token table 965a generated the minimum Nbits value 1930a of 1135, token table 965a will be used to encode the five unique literals 930, having literals counts 1910 as shown in FIG. 19a.

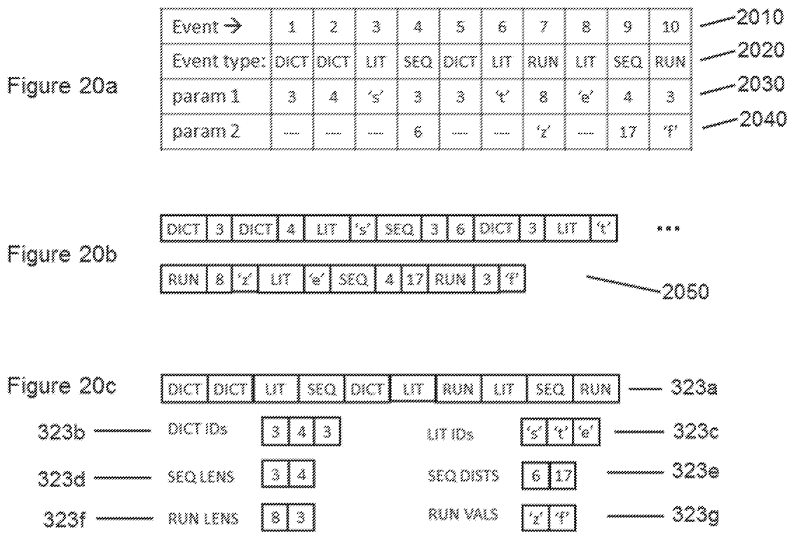

The example described in FIG. 20 illustrates that the disclosed technology may send the bits (fields) of each encoded block using different strategies. FIG. 20b illustrates a strategy that appends each event's parameters directly after each event's token. FIG. 20c illustrates a strategy that groups event parameters together in different block payloads 323. Each strategy has different advantages and disadvantages, Both strategies encode the input data using the same number of bits, and thus both strategies achieve the same compression of the data in this example input block,

FIG. 20a illustrates an example of a block to be encoded that contains ten events. Event types 2020 are selected from SEQ events 510, RUN events 520, LIT events 530, and DICT events 540, which were previously discussed in FIGS. 4 and 5, As previously shown in FIG. 4, each of the four event types are accompanied by 1 or 2 parameters, such as sequence length 414, sequence distance 416, run value 426, or literal value 434. In the example of FIG. 20a, param 1 row 2030 and param 2 row 2040 list the one or two parameters that are associated with each of the ten example event types 2020,

FIG. 20b illustrates a strategy that groups each event's parameters immediately following each event's token. FIG. 20b creates a serialized version 2050 of each of the fields of FIG. 20a.

In contrast, FIG. 20c illustrates a strategy that groups event parameter together in different block payloads 323a through 323g. After decoder 262 (not shown in FIG. 20c) decodes block payload 323a, which contains the block's event tokens, decoder 262 knows the number of each event type in the encoded block, as well as the order of events in the block, After decoding block payload 323a, decoder 232 knows that this example block contains three dictionary events (each having one parameter), three literal events (each having one parameter), two sequence events (each having two parameters), and two run events (each having two parameters), Next, decoder 232 decodes each of the parameters associated with each of the events, first decoding three dictionary event IDs from block payload 323b, then decoding three literal values from block payload 323c, then decoding two sequence lengths from block payload 323d, etc., until all parameters for all events 2020 have been decoded.

While the strategy described with FIG. 20b most closely matches the information presented for this example in FIG. 20a, it requires the most “state changes” in decoder 262. In software, a “state change” occurs every time a new event type 2020 occurs, Those familiar with programming techniques will recognize that such “state changes” require changes of control flow, either by using if-then/else constructs or switch case constructs, Such state changes may slow down the performance of decoder 262, In contrast, after decoding block payload 323a, which contains the list of all events in the block, in the proper sequence, decoder 262 then knows how many event types occur in the block. Because each event type has a fixed, known number of associated parameters that are known both to encoder 212 and decoder 262, decoder 262 can then decode the parameters WITHOUT “state changes.”

Thus the primary advantage of the strategy outlined in FIG. 20c may be that the number of “state changes” in decoder 232 is minimized using this strategy, when compared to the strategy of FIG. 20b. Minimizing “state changes” should result in faster performance of decoder 262, which those skilled in the art of programming would typically see as an implementation advantage.

Certain extensions of the disclosed technology are anticipated. For example, as shown in FIG. 10, encoder 212 may be implemented using two or more software threads, FPGA RTL hardware instances, or SoC (ASIC) hardware instances. Similarly, as shown in FIG. 11, decoder 262 may be implemented using two or more software threads, FPGA RTL hardware instances, or SoC (ASIC) hardware instances. Additional multi-Byte events that are not identified in this patent application may be detected by a future multi-Byte event detector 1010 as show in example encoder 212. Additional multi-Byte events may be decoded by decoder 262 in FIG. 11, resulting in additional (or modified) outputs from header decoder 1104 and payload decoder 1108. As described in FIGS. 14-18, two equivalent random access specifiers {startByte, NBytes} and {startByte, endByte} could be used by decoder 262 to specify the location of the desired decoded elements (typically Bytes).

A variety of implementations that use the present encoded block format are anticipated, such as software implementations that use Cloud micro-services, such as AWS Lambda, Microsoft Azure Functions, Google Compute Functions, or Docker containers. Similarly, FPGA implementations that use the present encoded block format are anticipated, such as FPGA implementations using Xilinx FPGAs in AWS F1 Instances, or Altera/Intel FPGAs in Microsoft Project Olympus. Similarly, SoC/ASIC implementations that use the present encoded block format are anticipated, such as in solid state disk (SSD) controllers manufactured by companies such as Samsung, Marvell, Silicon Motion, Phison, jMicron, etc. Other SoC/ASIC implementations that use the present encoded block format are anticipated that decrease the size and accelerate the transfer of data stored in dynamic random-access memory (DRAM), on-chip caches, and new memory technologies, such as the 3D Xpoint memory co-developed by Intel and Micron.

In a preferred embodiment, when the disclosed technology's encoded block size 215 set to a cache line size (typically 64 Bytes or 128 Bytes), encoder 212 will generate encoded blocks that conform to the disclosed technology's format. This use case (decreasing the size of data stored in cache lines and thus transferring the encoded data more quickly, relative to un-encoded cache lines, as well as increasing the capacity of DRAM and on-chip cache) is also anticipated by this application.

Instead of the header portion of the disclosed technology containing unique values (such as unique literals or sequence lengths) in descending frequency order, the unique values could alternately be sent in sequential order (from smallest to largest value, or from largest to smallest value), along with their frequency counts or frequency “position” in an ordered list. Typically this alternate encoding method would require more bits than the method described in most examples in this application, but the information could nevertheless be conveyed in this (or another) manner. The disclosed technology's can be embodied in first listing (enumerating) unique values in a header, and then by using that enumerated list in conjunction with a related payload whose list of values are encoded according to the enumerated list. There are multiple ways (including those methods listed above) to enumerate the list of unique parameters in a header.

The utility of the disclosed technology's encoded block format is not limited to those examples described in this specification, but is only limited by the claims associated with, or related to, the disclosed technology.

What is claimed is:

1. A method for lossless encoding of a data stream or file including a plurality of digital input values, comprising:
encoding a plurality of input blocks, each input block including a number Nb of digital input values from the plurality of digital input values, by generating a corresponding plurality of encoded blocks, each encoded block including three or more encoded events, and comprising:
a header describing three or more header elements of the three or more encoded events in the corresponding input block, and
a payload comprising parameters for corresponding header elements in the header of the three or more encoded events in the corresponding input block.

2. The method of claim 1, wherein header elements of the three or more header elements described by the headers in the corresponding plurality of encoded blocks comprise a data structure that represents one of the following:
a list of unique length-1 input values for length-1 input value events appearing in the original input values;
a list of unique sequence lengths from reference events appearing in the original input values;
a list of unique distance exponents from reference events appearing in the original input values;
a list of unique multi-Byte run values from run length events appearing in the original input values;
a list of unique run lengths from run length events appearing in the original input values; and
a dictionary of multi-Byte words from dictionary events appearing a plurality of times in the original input.

3. The method of claim 1, wherein the parameters in the payload of the three or more encoded events represent at least one of the following:
length-1 input values from the list of original input values;
a sequence length of reference events;
distances of reference events;
values of run events;
run lengths of run events; and
word identifiers of dictionary events.

4. The method of claim 1, in which the header conveys a dictionary of frequently-used multi-value sequences.

5. The method of claim 4, in which the dictionary is first sorted in frequency-of-use order, and then in word length order.

6. The method of claim 1, including receiving the plurality of input digital values in a processor including memory and a communication interface, and storing in the memory or transmitting on the communication interface, the corresponding plurality of encoded blocks, wherein the corresponding plurality of encoded blocks contains a sum of bits smaller than a sum of bits of the plurality of input blocks.

7. The method of claim 1, including decoding a selected encoded block into the number Nb of digital input values of the corresponding input block without loss of data.

8. The method of claim 2, in which one or both of the sequence lengths and run lengths have a minimum length of 2 Bytes.

9. The method of claim 2, in which at least one of the list of length-1 input values values, the list of multi-Byte reference distances, the list of run values, or the list of run lengths, is sent in a sorted order, either most-to-least frequent or least-to-most frequent.

10. The method of claim 1, in which the block size Nb of at least one of the plurality of input blocks is different than that of another block in the plurality of input blocks.

11. The method of claim 1, in which the block size Nb of the plurality of input blocks is constant.

12. The method of claim 1, further including providing a list of indices associated with the plurality of encoded blocks, wherein each index in the list of indices indicates the size of one of the encoded blocks in the plurality of encoded blocks, with which the index is associated.

13. The method of claim 1, further including providing a list of encoded block sizes, wherein each encoded block in a plurality of encoded blocks is associated with a block size entry on the list of encoded block sizes.

14. The method of claim 1, including using random access parameters specifying a range in the plurality of digital input values, such as a (startByte, NByte) pair or (startByte, endByte) pair, selecting one or more encoded blocks from the plurality of encoded blocks, and decoding the selected one or more encoded blocks into the digital input values without loss of data, to provide random access into the plurality of encoded blocks.

15. The method of claim 12, in which each index indicates the encoding method of the associated encoding block, chosen from at least one of the following:
an encoding method for already-compressed data;
an encoding method for numerical data; and
a default encoding method.

16. The method of claim 1, in which an encoding method of an encoded block is also contained in the encoded block header or payload, and in which the encoding method includes at least one of the following:
an encoding method for already-compressed data;
an encoding method for numerical data; and
a default encoding method.

17. The method of claim 1, in which the header precedes the payload.

18. The method of claim 1, in which the payload precedes the header.

19. The method of claim 1, in which Nb varies from block to block.

20. A system for communicating or storing data, comprising
a processor including memory and a communication interface, configured to receive a file or stream including a plurality of input digital values, and execute a method according to any of claims 1-19, and configured to store in the memory or transmit on the communication interface, the corresponding plurality of encoded blocks, wherein the corresponding plurality of encoded blocks is encoded without loss of data, and contains a sum of bits smaller than a sum of bits of the plurality of input blocks.
